(19) United States
(12) Patent Application Publication
(10) Pub. No.: US 2013/0164487 A1
(43) Pub. Date: Jun. 27, 2013

(54) ENCAPSULATION AND PRODUCTION OF AN ENCAPSULATED PRINTED CIRCUIT BOARD ASSEMBLY

(71) Applicant: Florian Eder, Erlangen (DE)

(72) Inventor: Florian Eder, Erlangen (DE)

(21) Appl. No.: 13/822,079

(22) PCT Filed: Aug. 17, 2011
(86) PCT No.: PCT/EP2011/064124

§ 371 Date: Mar. 11, 2013

(30) Foreign Application Priority Data
Sep. 10, 2010 (DE) 10 2010 045 035.9

(51) Int. Cl. H05K 3/28; H05K 1/02

(52) U.S. Cl. CPC H05K 3/284; H05K 1/0213
USPC 428/76; 427/96.2; 427/578; 427/96.4

(57) ABSTRACT

An encapsulation is formed on a printed circuit board that is populated with electronic components, especially a printed circuit board having electronic components that have to meet certain safety standards because they are used, e.g. in the area of explosion control. The printed circuit board assembly is coated with a bottom layer, preferably a bottom layer produced from a plasma and pretreated such that the protective coat adheres on the entire surface of the printed circuit board assembly evenly and in a sufficient thickness and does not shrink during the subsequent curing process regardless of the material of the surface and/or regardless of the fact whether the coat is applied to a geometrically problematic area on the printed circuit board assembly such as a corner or an edge.

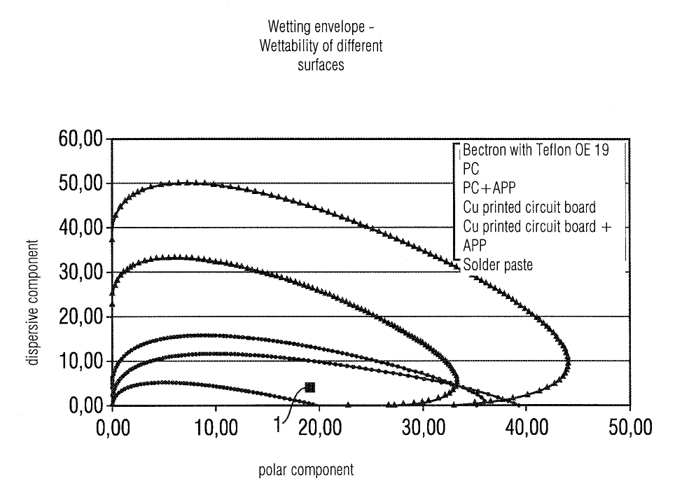

### CROSS REFERENCE TO RELATED APPLICATIONS

This application is based on and hereby claims priority to International Application No. PCT/EP2011/064124 filed on Aug. 17, 2011 and German Application No. 10 2010 045 035.9 filed on Sep. 10, 2010, the contents of which are hereby incorporated by reference.

### BACKGROUND

The invention relates to an improved protective coating/encapsulation for a printed circuit board that is populated with electronic components.

Typically, electronic components are mounted on electronic printed circuit boards which when in service are exposed to the most disparate environmental influences. Thus, humidity, variations in temperature, aggressive media such as acids, salts and/or corrosive gases in different degrees of astringency and/or concentration lead to more or less rapid failure of a printed circuit board and/or the electronic components mounted thereon. For this reason the populated printed circuit boards are coated with an encapsulating protective lacquer that is several to several hundred μm thick as protection against undesirable environmental influences.

A populated printed circuit board is a printed circuit board on which are mounted electronic components or electronic modules which are either simply grouped together or partially assembled in combination with one another to produce a circuit and/or are in communication in some other way. Such components can include for example transistors, diodes, capacitors, light-emitting components and other electronic components. Accordingly, a typical printed circuit board comprises a broad mix of the widest variety of materials on the surface, such as e.g. metal, resin, hybrid materials and/or plastic, all of which must be wetted by the protective lacquer employed in order to ensure the entire surface is sealed within a reliable protective lacquer coating.

A frequent practice in order to improve the wetting of the lacquer is to mix in additional solvents which, although initially improving the wetting of the lacquer, conversely alter and impair the protective effect of the protective lacquer and/or its workability, such as drying time, flow characteristics, etc. Achieving certain lacquer densities is also often difficult with lacquers that have been strongly diluted and/or adulterated with solvents. In particular after the solvent has evaporated there may be signs of dewetting of the lacquer, which means that the lacquer starts to recede away from geometrically problematic points that it initially covered. A defect is produced in the lacquer coating.

Using solvents to improve the wetting of the surfaces also has a detrimental effect on the wetting at the edges and corners, as well as detracting from the assurance of a uniformly thick protective lacquer coating. Finally, blowholes sometimes also develop within the protective lacquer coating.

For this reason all safety-relevant parts are currently coated using very complicated and elaborate methods. Thus, for example, a dual lacquer coating process is employed in which the printed circuit board is initially coated over its entire surface with a first layer of lacquer and after the coating has cured the critical areas are then covered with a thick-film lacquer using the dispersion method. This leads to a considerable additional overhead (2× coating, 2× curing, 2× lacquer storage, 2 different plants), which is reflected in the manufacturing costs. It has also not been established thus far in the related art which defects may occur at the interface between the two lacquers, e.g. migration paths or cracks due to thermal shock.

### SUMMARY

It is therefore one possible object to provide an encapsulation of a populated printed circuit board in which the different surfaces of the printed circuit board and also the geometric problem points such as corners and edges are at least wetted by protective lacquer or even coated therewith homogeneously and/or to a uniform thickness.

The inventor proposes a dual-layer encapsulation for a populated printed circuit board, comprising a bottom layer and a protective lacquer coating, wherein the printed circuit board is covered with the bottom layer which has a surface to which the top layer, i.e. the protective lacquer, readily adheres, wherein the top protective lacquer coating is thicker than the bottom layer lying thereunder and the top protective lacquer coating protects the populated printed circuit board against undesirable and/or harmful environmental influences. The inventor also proposes a method for encapsulating a populated printed circuit board, wherein the populated printed circuit board is first covered with a bottom layer and second, a thicker, top protective layer formed of a protective lacquer is applied onto the covering bottom layer.

According to an advantageous embodiment variant of the method, the bottom layer is applied by a plasma coating method.

According to an advantageous embodiment variant of the method, the protective lacquer coating is applied from the liquid phase by way of a process selected from the following group of processes: spray or curtain coating, dip coating or swirl coating.

According to a particularly advantageous embodiment variant, the bottom layer is applied by an atmospheric pressure plasma (APP) technique.

According to another advantageous embodiment variant, the layer thickness of the bottom layer is less than/equal to 150 nm, particularly preferably less than/equal to 100 nm, even more preferably less than/equal to 50 nm and in particular less than/equal to 20 nm.

According to an advantageous embodiment variant, the plasma coating method is performed using an organosilicon compound as precursor.

Use is preferably made of vaporized hexamethyldisiloxane or tetraethoxysilane as precursors. The use of organic precursors, in particular various gaseous hydrocarbons such as acetylene or methane, as well as any mixtures, is also conceivable.

Depending on the precursor used, either compressed air or nitrogen is employed as the reaction gas. In the case of purely organic precursors, forming gas can also be used. Plasma frequencies of 16 to 21 kHz have proven advantageous, in which case the precursor flow when an organosilicon precursor is used should amount to approx. 5 to 20 g/h.

An example of a protective lacquer is the thin-film lacquer PL 4122 of the company Elantas, which wets completely on plastics such as polycarbonate (PC) and on copper (Cu), in particular when it is mixed with petroleum ether.

The protective lacquer can also contain solvents, petroleum ether for example.

### BRIEF DESCRIPTION OF THE DRAWING

These and other objects and advantages of the present invention will become more apparent and more readily appreciated from the following description of the preferred embodiments, taken in conjunction with the accompanying drawing of which:

The sole FIGURE shows a graph for comparing the wettability of printed circuit board surfaces with and without bottom layer.

### DETAILED DESCRIPTION OF THE PREFERRED EMBODIMENT

Reference will now be made in detail to the preferred embodiments of the present invention, examples of which are illustrated in the accompanying drawing, wherein like reference numerals refer to like elements throughout.

The wettability of the traditional surfaces of a populated printed circuit board such as solder paste, polycarbonate and copper, for example, are shown in what is termed the “wetting envelope”, wherein a dispersive and a polar component of the surface span a coordinate system. Thin-film lacquers having a high solvent component, such as Elantas PL 4122, for example, are optimized to provide good wetting and lie in these graphical representations as points such that they are enclosed by the curves of the respective surfaces in the aforementioned coordinate system. The cited lacquer Elantas PL 4122 is represented in the FIGURE as point 1. This then means good wettability of the surface forming the curve by the lacquer represented as a point. Lacquers having better flow characteristics than the aforesaid Elantas PL 4122 possess far higher dispersive and polar components and would then lie for example outside the curve of the copper (Cu) surface or the polycarbonate (PC) surface, i.e. for example at the point given by polar component “40.00” and dispersive component “20.00”.

By a plasma coating, however, the surfaces of the two materials (Cu) and (PC) can therefore be modified into the surfaces (Cu+APP) and (PC+APP) such that lacquers having higher polar and dispersive components will also wet effectively. This is strikingly illustrated in the FIGURE by the curves plotted for Cu printed circuit board+APP and PC+APP. In this case APP stands for atmospheric pressure plasma.

With the bottom layer, higher-viscosity protective lacquers, for example, which, though previously associated with wetting problems, on the other hand demonstrated advantages in terms of flow behavior, can be used for the encapsulation. With the proposed bottom layer, the lacquer coating can be applied in a single process used in the related art such as e.g. curtain coating. The bottom layer, which is only a few nanometers thick, can be applied inline and is effective immediately.

As well as financial advantages in terms of the production method, this type of pretreatment also delivers benefits in terms of process reliability, in two respects. On the one hand the lacquer coating henceforth includes just a single lacquer, not, as previously, at least partially of two lacquer coatings on a printed circuit board. Encapsulation according to current practice—at least in the case of safety-relevant parts—is carried out in such a way that firstly lacquer is applied over the entire printed circuit board and then the critical areas are coated once again with a thick paste so that also of course no exposed points remain. Apart from the cost disadvantage compared with the proposed encapsulation, this also produces boundaries in the lacquer which are avoided according to the inventor's proposals. On the other hand the bottom layer effects a much better adhesion behavior of the lacquer on the coated substrate, with the result that cracks or lacquer delaminations occur less often in the event of thermal shocks.

In particular the variant in which the bottom layer is applied as plasma distinguishes itself from known surface adaptation and adhesion promoting processes in particular in that in this case the protective lacquer application takes place ideally immediately following the plasma coating, in particular however preferably within a time interval of three days, so that the plasma layer is still capable of reacting during this period and consequently can form an optimal bond with the protective lacquer coating.

### Example

In a comparison example, an encapsulation using a protective lacquer coating formed of the UV-curing protective lacquer PT 4600 of the company Elantas was applied firstly to a populated printed circuit board not pretreated with a bottom layer, and secondly to a populated printed circuit board pretreated beforehand with a plasma bottom layer. The thickness of the plasma layer was in the range of approximately 5 nm.

The protective lacquer was applied by dispersion.

After a few seconds the protective lacquer on the populated and untreated comparison printed circuit board receded again completely from the corners and edges, with the result that only a patch of the protective layer can be seen in the center of the printed circuit board.

A different result was obtained in the case of the pretreated printed circuit board covered by a bottom layer: here, the protective lacquer wets completely, including at the corners and edges. The difference between the populated, untreated printed circuit board very inadequately encapsulated with a central patch of protective lacquer and the populated printed circuit board having the bottom layer as a result of a plasma pretreatment can be seen with the naked eye. The printed circuit board with bottom layer reveals a complete encapsulation by the protective lacquer, so no surface defect can be detected with the naked eye.

The good wetting with protective lacquer on the populated printed circuit board with bottom layer was also successfully maintained in its entirety during the UV curing process.

It was also confirmed with the aid of a microsection examined under the microscope that thanks to the bottom layer the edges were likewise completely wetted with protective lacquer. It was revealed in a SEM micrograph that the edge was covered by a continuous protective lacquer coating with a thickness of approx. 20 μm.

According to the proposal, a bottom layer or a pretreatment of a printed circuit board by atmospheric pressure plasma coating methods is disclosed by which it is possible to modify the surface properties of the coated substrate in a targeted manner and adapt them to the protective lacquer. Because the application of this special adhesion promoter is effected from the gas phase, the most complete coating possible of the printed circuit board can be achieved, irrespective of the topography or the materials used. By the bottom layer it becomes possible to create identical surface conditions and consequently wetting conditions on a printed circuit board.

The proposal relates to an improved encapsulation for a printed circuit board populated with electronic components, in particular for a printed circuit board having electronic components that have to meet safety standards because they are deployed for example in environments that are subject to explosion protection requirements. Toward that end, the populated printed circuit board is covered with a bottom layer, preferably a bottom layer produced from a plasma, and pretreated such that the protective lacquer coating adheres uniformly and with a sufficient thickness over the entire surface of the populated printed circuit board, irrespective of the material of the surface and/or regardless of whether a geometric problem point such as a corner or an edge, for example, is present on the populated printed circuit board, and also does not contract during an ensuing curing process.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-9. (canceled)

10. An encapsulated circuit board, comprising:
a populated printed circuit board; and
a dual-layered encapsulation comprising:
a bottom layer covering the printed circuit board; and
a protective lacquer coating formed on the bottom layer, the bottom layer having a surface to which the protective lacquer coating readily adheres, the protective lacquer coating being thicker than the bottom layer, the protective lacquer coating protecting the populated printed circuit board against undesirable and/or harmful environmental influences.

11. The encapsulated circuit board as claimed in claim 10, wherein the bottom layer is a plasma coating.

12. The encapsulated circuit board as claimed in claim 10, wherein the bottom layer is a plasma coating produced from an organosilicon precursor and/or a gaseous hydrocarbon compound precursor.

13. The encapsulated circuit board as claimed in claim 10, wherein the bottom layer has a layer thickness less than 150 nm.

14. The encapsulated circuit board as claimed in claim 12, wherein the bottom layer has a layer thickness less than 150 nm.

15. The encapsulated circuit board according to claim 10, wherein the bottom layer is a coating other than a lacquer coating.

16. A method for encapsulating a printed circuit board, comprising:
covering a populated printed circuit board with a bottom layer; and
applying a thicker, top protective layer onto the bottom layer, the top protective layer being formed of a protective lacquer.

17. The method as claimed in claim 16, wherein
the bottom layer is applied in a plasma and/or from a gas phase onto the populated printed circuit board, and
the top protective layer is applied from a liquid phase onto the bottom layer.

18. The method as claimed in claim 17, wherein the bottom layer is applied onto the populated printed circuit board in an atmospheric pressure plasma.

19. The method as claimed in claim 16, wherein the top protective layer is applied within three days of covering the populated printed circuit board with the bottom layer.

20. The method as claimed in claim 16, wherein the top protective layer is applied immediately following covering the populated printed circuit board with the bottom layer.

21. The method as claimed in claim 18, wherein the top protective layer is applied immediately following covering the populated printed circuit board with the bottom layer.

22. The method as claimed in claim 16, wherein the bottom layer has a layer thickness less than 150 nm.

23. The method according to claim 16, wherein the bottom layer is a coating other than a lacquer coating.
